(19) United States
(12) Patent Application Publication
(10) Pub. No.: US 2026/0247686 A1
(43) Pub. Date: Aug. 20, 2026

(54) HKMG DEVICE AND METHOD FOR MANUFACTURING SAME

(71) Applicant: Shanghai Huali Integrated Circuit Corporation, Shanghai (CN)

(72) Inventors: Jionghan YE, Shanghai (CN); Yu XIA, Shanghai (CN); Changfeng WANG, Shanghai (CN)

(73) Assignee: Shanghai Huali Integrated Circuit Corporation, Shanghai (CN)

(21) Appl. No.: 19/538,948

(22) Filed: Feb. 12, 2026

(30) Foreign Application Priority Data
Feb. 19, 2025 (CN) 2025101873855

(51) Int. Cl. H10D 64/66; H10D 64/01; H10D 84/01

(52) U.S. Cl. CPC H10D 64/667; H10D 64/017; H10D 84/0177

(57) ABSTRACT

An HKMG device and a method for manufacturing same. By separately forming the first groove in the PMOS region and the second groove in the NMOS region, depositing the first filling layer in the PMOS region and the second filling layer in the NMOS region, then removing the first and second filling layers through a combination of dry and wet etching and filling the grooves with metal material to respectively form the PMOS and NMOS metal gates, this method allows for precise control over etching depth and range, preventing interface damage to the PMOS region; it eliminates chamfer formation at the junction, prevents wet etching solutions from penetrating the PMOS metal gate, and resolves corrosion defects caused by chemical reactions; furthermore, the PMOS and NMOS work function metal layers are formed stepwise, with chemical mechanical polishing ensuring a uniform surface, significantly enhancing the performance and reliability of the HKMG device.

### FIELD OF THE INVENTION

The present disclosure relates to the field of semiconductor technologies, and in particular, to a high-k metal gate (HKMG) device and a method for manufacturing the same.

### BACKGROUND OF THE INVENTION

Advancements in chip technology have not only driven the evolution of intelligent systems, but also greatly improved people’s everyday life by making information access more efficient and smooth. In this context, optimizing the performance of metal-oxide-semiconductor field-effect transistors (MOSFETs), the core components of chips, has become increasingly important. Early MOS transistors in integrated circuits featured polycrystalline silicon gates, known as Poly Gate. However, as transistor dimensions shrink, traditional polycrystalline silicon gates experienced performance degradation partly due to boron penetration effects. In addition, unavoidable depletion effects increased the effective dielectric thickness of the gate, reducing gate capacitance and ultimately impairing device performance. To meet growing performance demands, polycrystalline silicon gates are being gradually replaced with metal gates. The application of metal gates significantly enhances MOS transistor switching characteristics and further optimizes overall chip functionality.

MOS transistors are categorized into two types, PMOS and NMOS, each with distinct operating principles and electrical characteristics. As a result, metal gate fabrication must be customized to suit the specific requirements of PMOS and NMOS transistors. Specifically, it involves introducing different types and thicknesses of work function metal thin film layers within the metal gate to fine-tune the device’s threshold voltage. Currently, two main approaches are used in the industry to fabricate metal gate structures for NMOS and PMOS. The first method involves removing polycrystalline silicon completely from both NMOS and PMOS regions, followed by a deposition-lithography-etching process to form work function metal thin film layers of various thickness in each region; the metal gate is then completed by filling with metal materials. The second method begins by removing polycrystalline silicon from the PMOS region, filling in with metal material, followed by planarizing it using a chemical mechanical polishing process; subsequently, the polycrystalline silicon in the NMOS region is removed, filled with metal, and polished in the same manner. However, researchers have observed that during NMOS polycrystalline silicon removal, unavoidable damage occurs at the interface between NMOS and PMOS, leading to chamfer formation. As a result, when the NMOS region undergoes subsequent cleaning, wet etching solutions may seep into the PMOS metal gate, which in turn can trigger unwanted chemical reactions with the PMOS gate material. This corrosion defect not only compromises device performance and reliability, but can also ultimately lead to device failure.

In light of these challenges, there is an urgent need for a new HKMG device structure and a corresponding manufacturing method that effectively addresses interface damage and corrosion defects, thereby enhancing device performance and reliability.

It should be noted that the above introduction to the technical background is only for the convenience of a clear and complete description of the technical solution of the present disclosure. It is intended to facilitate understanding among those skilled in the field and should not be construed as an indication that the disclosed technical solutions are already well known in the industry simply because they appear in the background section of the present disclosure.

### SUMMARY OF THE INVENTION

The present disclosure provides an HKMG device and a method for manufacturing same, which address chamfer formation at the NMOS-PMOS junction during the stepwise metal gate fabrication process, thereby preventhing cleaning solutions from penetrating the PMOS metal gate and mitigating corrosion defects, as a result, enhancing device performance and reliability.

The presently disclosed method for manufacturing the HKMG device comprises steps S1-S7.

Step S1 comprises: providing a substrate, forming a high-k dielectric layer, a first isolation layer, and a dummy gate layer on the substrate, and configuring the dummy gate layer with a side wall and an interlayer dielectric layer on each side.

Step S2 comprises: forming a first photoresist layer on the dummy gate layer, and opening a portion of the dummy gate layer by photolithography and etching to form a first groove for defining an NMOS region and a PMOS region, and removing the first photoresist layer.

Step S3 comprises: forming a first bottom barrier layer, a first work function metal layer and a first top barrier layer on a bottom and side walls of the first groove on the substrate in the PMOS region.

Step S4 comprises: forming a first filling layer on the first top barrier layer, completely filling the first groove with the first filling layer, followed by polishing the top of the first filling layer to be flush with the top of each interlayer dielectric layer with a chemical mechanical polishing process.

Step S5 comprises: forming a first hard mask layer, in another patterning process, a second photoresist layer (not shown as an intermediate layer) on the first filling layer, removing the first hard mask layer and the dummy gate layer in the NMOS region by photolithography and etching to form a second groove, and removing the second photoresist layer.

Step S6 comprises: forming a second bottom barrier layer, a second work function metal layer and a second top barrier layer on a bottom and side walls of the second groove on the substrate in the NMOS region, forming a second filling layer on the second top barrier layer, and filling the second groove with the second filling layer completely, followed by polishing the top of the second filling layer to be flush with the top of the first filling layer with a chemical mechanical polishing process.

Step S7 comprises: removing the first filling layer and the second filling layer by etching, depositing a metal material in the first groove and the second groove to respectively form a first metal gate and a second metal gate, and using a chemical mechanical polishing process to make the surface of the first metal gate and the surface of the second metal gate flush.

Optionally, the first work function metal layer is a P work function metal layer, and the second work function metal layer is an N work function metal layer.

Optionally, a material of the P work function metal layer comprises TiN, and a material of the N work function metal layer comprises TiAl.

Optionally, the first bottom barrier layer comprises a first barrier layer and a second barrier layer which are stacked. A material of the first barrier layer comprises TaN and TiN, and a material of the second barrier layer comprises TiN.

Optionally, the first filling layer and the second filling layer are made of the same material and are both amorphous silicon. The dummy gate layer is made of the same material as the first filling layer and the second filling layer.

Optionally, the first metal gate and the second metal gate are made of the same material, comprising Al, W, and Ti.

Optionally, removing the first hard mask layer and the dummy gate layer in the NMOS region comprises: removing the first hard mask layer by a dry etching process, and removing the dummy gate layer by a wet etching process. An etching solution of the wet etching process is a hydrochloric acid solution.

Optionally, the presently disclosed method further comprises: removing a portion of the first hard mask layer from above the NMOS region, wherein this being removed portion is slightly larger than the area of the NMOS region into the PMOS region, meanwhile keeping the PMOS region unexposed after removing said portion of the first hard mask layer.

Optionally, a total thickness of the first bottom barrier layer, the first work function metal layer and the first top barrier layer is greater than a total thickness of the second bottom barrier layer, the second work function metal layer and the second top barrier layer.

The presently disclosed HKMG device is manufactured using any of the aforementioned method embodiments.

As described above, the disclosed HKMG device and manufacturing method offer several advantages. By separately forming the first groove in the PMOS region and the second groove in the NMOS region, depositing the first filling layer in the PMOS region and the second filling layer in the NMOS region, then removing the first filling layer and the second filling layer through a combination of dry and wet etching and filling the grooves with metal material to respectively form the first and second metal gates, this method allows for precise control over etching depth and range, preventing interface damage to the PMOS region when removing polysilicon from the NMOS region in conventional processes; it effectively eliminates chamfer formation at the junction, prevents wet etching solutions from penetrating the PMOS metal gate, and fundamentally resolves corrosion defects caused by chemical reactions between wet etching solutions and metals like aluminum in traditional processes; furthermore, the PMOS and NMOS work function metal layers are formed stepwise, with chemical mechanical polishing ensuring a uniform surface, significantly enhancing the performance and reliability of the HKMG device.

### BRIEF DESCRIPTION OF DRAWINGS

FIG. 1 is a flow chart of a method for manufacturing an HKMG device according to the present disclosure.

FIG. 2 is a schematic cross-sectional view of an intermediate structure obtained after forming a high-k dielectric layer, a first isolation layer, a dummy gate layer, two side walls, and two interlayer dielectric layers on a substrate according to the present disclosure.

FIG. 3 is a schematic cross-sectional view of an intermediate structure obtained after forming a first groove according to the present disclosure.

FIG. 4 is a schematic cross-sectional view of an intermediate structure obtained after forming a first bottom barrier layer, a first work function metal layer, and a first top barrier layer according to the present disclosure.

FIG. 5 is a schematic cross-sectional view of an intermediate structure obtained after forming a first filling layer according to the present disclosure.

FIG. 6 is a schematic cross-sectional view of an intermediate structure obtained after forming a first hard mask layer according to the present disclosure.

FIG. 7 is a schematic cross-sectional view of an intermediate structure obtained after forming a second groove according to the present disclosure.

FIG. 8 is a schematic cross-sectional view of an intermediate structure obtained after forming a second bottom barrier layer, a second work function metal layer and a second top barrier layer according to the present disclosure.

FIG. 9 is a schematic cross-sectional view of an intermediate structure obtained after forming a second filling layer according to the present disclosure.

FIG. 10 is a schematic cross-sectional view of an intermediate structure obtained after forming a first metal gate and a second metal gate according to the present disclosure.

### REFERENCE NUMERALS

10: Substrate; 11: High-k dielectric layer; 12: First isolation layer; 13: Dummy gate layer; 141: Side wall; 142: Interlayer dielectric layer; 15: First groove; 16: First bottom barrier layer; 161: First barrier layer; 162: Second barrier layer; 17: First work function metal layer; 18: First top barrier layer; 19: First filling layer; 20: First hard mask layer; 21: Second groove; 22: Second bottom barrier layer; 23: Second work function metal layer; 24: Second top barrier layer; 25: Second filling layer; 26: First metal gate; 27: Second metal gate; and S1-S7: steps S1 to S7.

### DETAILED DESCRIPTION OF THE INVENTION

The embodiments of the present disclosure will be described below. Those skilled can easily understand disclosure advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

For example, when the embodiments of the present disclosure are described in detail, for ease of description, the cross-sectional view showing the device structure will not be partially enlarged according to the general scale, and the schematic diagram is only an example, which should not restrict the scope of protection. In addition, the actual production should include the length, width and depth of the three-dimensional space dimensions.

For the convenience of description, spatial relation terms such as "below", "under", "beneath", "on", "above", "up", etc. may be used herein to describe the relationships between an element or feature and other elements or features. It will be understood that these spatial relationship terms are intended to encompass directions/orientations of the device in use or operation other than those depicted in the drawings.

In the context of this disclosure, the structure described with a first feature "on top" of a second feature may include embodiments where the first and second features are formed in direct contact, or it may include embodiments where additional features are formed between the first and second features such that the first and second features are not in direct contact.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components’ layout may also be more complicated.

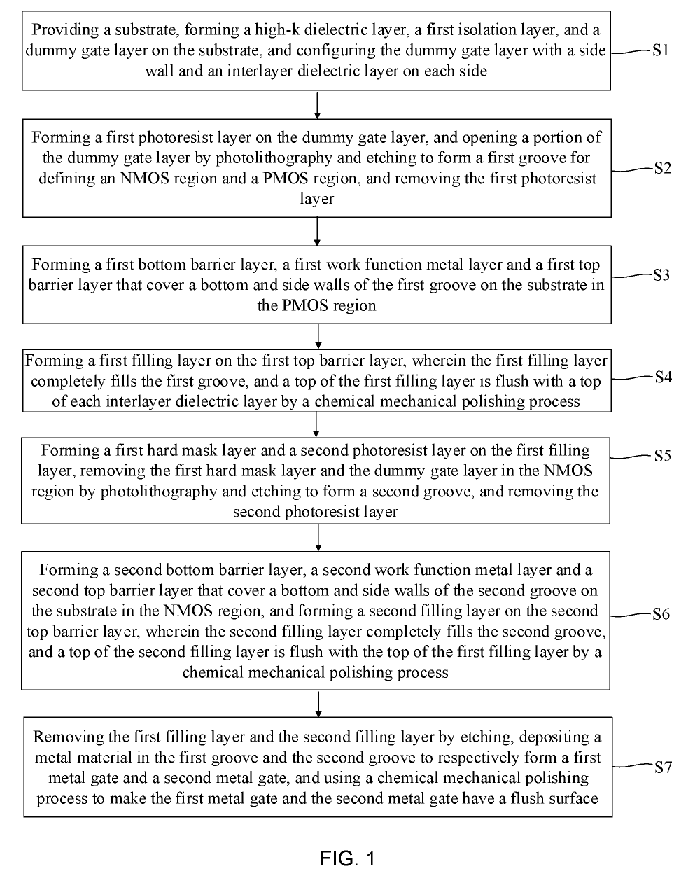

As shown in FIG. 1, the present disclosure provides a method for manufacturing an HKMG device. The method comprises steps S1-S7.

Step S1 comprises: providing a substrate 10, forming a high-k dielectric layer 11, a first isolation layer 12, and a dummy gate layer 13 on the substrate 10, and configuring the dummy gate layer 13 with a side wall 141 and an interlayer dielectric layer 142 on each side.

Step S2 comprises: forming a first photoresist layer on the dummy gate layer 13, and opening a portion of the dummy gate layer 13 by photolithography and etching to form a first groove 15 for defining an NMOS region and a PMOS region, and removing the first photoresist layer.

Step S3 comprises: forming a first bottom barrier layer 16, a first work function metal layer 17 and a first top barrier layer 18 on a bottom and side walls of the first groove 15 on the substrate 10 in the PMOS region.

Step S4 comprises: forming a first filling layer 19 on the first top barrier layer 18. The first filling layer 19 completely fills the first groove 15, and a top of the first filling layer 19 is flush with a top of each interlayer dielectric layer 142 by a chemical mechanical polishing process.

Step S5 comprises: forming a first hard mask layer 20 and a second photoresist layer (not shown as an intermediate layer) on the first filling layer 19, removing the first hard mask layer 20 and the dummy gate layer 13 in the NMOS region by photolithography and etching to form a second groove 21, and removing the second photoresist layer.

Step S6 comprises: forming a second bottom barrier layer 22, a second work function metal layer 23 and a second top barrier layer 24 on a bottom and side walls of the second groove 21 on the substrate 10 in the NMOS region, and forming a second filling layer 25 on the second top barrier layer 24. The second filling layer 25 completely fills the second groove 21, and a top of the second filling layer 25 is flush with the top of the first filling layer 19 by a chemical mechanical polishing process.

Step S7 comprises: removing the first filling layer 19 and the second filling layer 25 by etching, depositing a metal material in the first groove 15 and the second groove 21 to respectively form a first metal gate 26 and a second metal gate 27, and using a chemical mechanical polishing process to make the first metal gate 26 and the second metal gate 27 have a flush surface.

The method for manufacturing the HKMG device will be described in detail below with reference to the accompanying drawings.

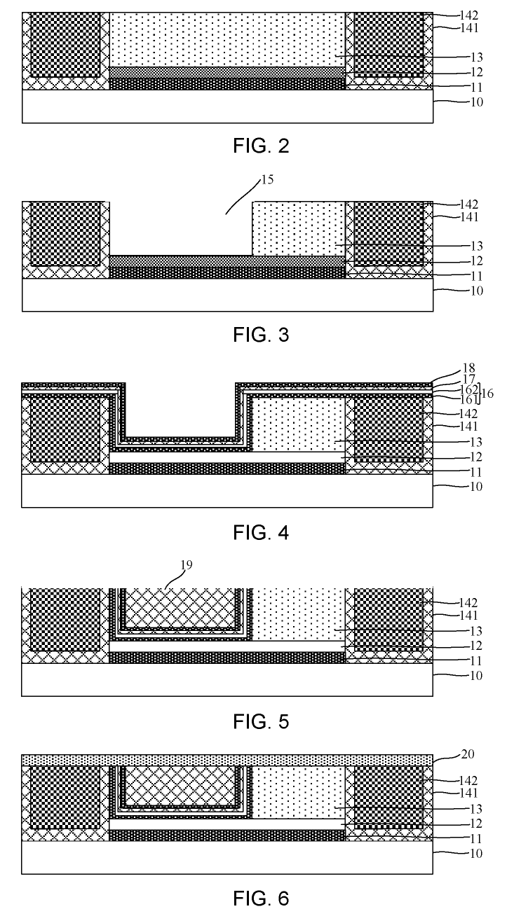

In step S1, referring to FIGS. 1 and 2, the high-k dielectric layer 11, the first isolation layer 12 and the dummy gate layer 13 are formed on the provided substrate 10. The dummy gate layer 13 is configured with two side walls 141 and two interlayer dielectric layers 142, with one side wall 141 and one interlayer dielectric layer 142 on each side.

As an example, the substrate 10 may be a single crystal, polycrystalline or amorphous silicon substrate, or silicon-on-insulator (SOI), and may also comprise other types of semiconductor materials, such as germanium, silicon carbide (SiC), or silicon germanium (SiGe).

Specifically, as shown in FIG. 2, the substrate 10 is a common monocrystalline silicon substrate 10.

As shown in FIG. 2, the high-k dielectric layer 11, the first isolation layer 12 and the dummy gate layer 13 are sequentially formed above the substrate 10. The high-k dielectric layer 11 represents a dielectric layer with a dielectric constant greater than 3.5, such as chromium oxide, aluminum oxide, hafnium oxide, etc., and the high-k dielectric layer 11 may be formed by a chemical vapor deposition process or an atomic layer deposition process. Preferably, a material of the high-k dielectric layer 11 is hafnium dioxide. Optionally, a material of the first isolation layer 12 comprises any one of silicon oxide, silicon nitride, silicon oxynitride, silicon carbide, silicon carbonitride, boron nitride, tantalum nitride, and titanium nitride; for example, the first isolation layer 12 may be a titanium nitride layer. Preferably, a material of the dummy gate layer 13 is amorphous silicon. One side wall 141 and one interlayer dielectric layer 142 surrounded by said side wall 141 are formed on both the left side and the right side of the dummy gate layer 13. The side wall 141 and the substrate 10 are arranged in a contact manner, and optionally, a material of the side wall 141 comprises at least one of silicon nitride and silicon dioxide. Optionally, a material of the interlayer dielectric layer 142 comprises silicon oxide, silicon nitride, or other suitable dielectric materials. Specifically, in the present disclosure, the side wall 141 is made of silicon nitride, and the interlayer dielectric layer 142 is made of silicon oxide.

In step S2, referring to FIGS. 1 and 3, from a patterning process, the first photoresist layer (not shown as an intermediate layer) is formed on the dummy gate layer 13, a portion of the dummy gate layer 13 is removed by photolithography and etching to form the first groove 15 for defining the NMOS region and the PMOS region, and then the first photoresist layer is removed.

Specifically, a photoresist is deposited on the dummy gate layer 13 to form the first photoresist layer, then a first notch is formed in the first photoresist layer using a photolithography process, so as to expose a to-be-etched region of the dummy gate layer 13 beneath the first notch. A width of the first notch determines a width of the subsequently formed PMOS region, as shown in FIG. 3. The exposed to-be-etched region of the dummy gate layer 13 beneath the first notch is removed by a dry etching process to form the first groove 15, and then the remaining portion of the first photoresist layer is removed. The first groove 15 is used to define the boundaries of the PMOS region and the NMOS region.

Specifically, the first photoresist layer may be removed using an ashing method.

In step S3, referring to FIGS. 1 and 4, the first bottom barrier layer 16, the first work function metal layer 17 and the first top barrier layer 18 on the bottom and the side walls of the first groove 15 are sequentially formed on the substrate 10 in the PMOS region.

FIG. 4 shows a schematic cross-sectional view of an intermediate structure obtained after forming the first bottom barrier layer 16, the first work function metal layer 17 and the first top barrier layer 18. The first bottom barrier layer 16 comprises a first barrier layer 161 and a second barrier layer 162 which are stacked.

Specifically, the first bottom barrier layer 16 prevents metal gate diffusion in the PMOS region, blocking the metal gate from migrating into the first isolation layer 12, preserving the dielectric performance of the first isolation layer 12, and thereby enhancing the overall performance of the HKMG device.

As an example, a material of the first barrier layer 161 comprises TaN and TiN, and a material of the second barrier layer 162 comprises TiN. In the present disclosure, the first barrier layer 161 is made of TaN, while the second barrier layer 162 is made of TiN. Compared to a single barrier layer, multiple stacked barrier layers composed of different materials offer superior metal gate diffusion blocking capability. Since TiN is less effective at blocking metal gate diffusion than TaN, while TaN has lower electrical conductivity than TiN, a TiN/TaN stacked structure is used instead of a single TaN layer, which enhances the diffusion-blocking capability of the first bottom barrier layer 16 and reduces the resistance of the first bottom barrier layer 16 (compared to a single TaN layer).

Specifically, the method of forming the first barrier layer 161 and the second barrier layer 162 comprises a sputtering method, a metal compound vapor deposition method, a molecular beam epitaxy method, an atomic vapor deposition method, an atomic layer deposition method, or other suitable methods.

Specifically, under the condition that the performance of the HKMG device is ensured, the thicknesses of the first barrier layer 161 and the second barrier layer 162 can be adjusted according to actual situations.

As an example, the method of forming the first work function metal layer 17 comprises a sputtering method, a physical vapor deposition method, a chemical vapor deposition method, a metal compound vapor deposition method, a molecular beam epitaxy method, an atomic vapor deposition method, an atomic layer deposition method, or other suitable methods.

Specifically, in the present disclosure, the first work function metal layer 17 is a P work function metal layer, TiN is used to form the P work function metal layer, the effective work function of the HKMG device is adjusted using the first work function metal layer 17, so that the Fermi level of the PMOS region is close to the top of the valence band of the substrate 10, and then the metal gate process is compatible with the integrated circuit process.

Specifically, under the condition that the performance of the HKMG device is ensured, the thickness of the first work function metal layer 17 can be adjusted according to actual situations.

As an example, the method of forming the first top barrier layer 18 comprises a sputtering method, a physical vapor deposition method, a chemical vapor deposition method, a metal compound vapor deposition method, a molecular beam epitaxy method, an atomic vapor deposition method, an atomic layer deposition method, or other suitable methods.

As an example, a material of the first top barrier layer 18 comprises TiN or other suitable conductive materials. In the present disclosure, the first top barrier layer 18 is a TiN thin film layer.

As an example, a thickness of the first top barrier layer 18 is less than a thickness of the first bottom barrier layer 16.

Specifically, under the condition that the performance of the HKMG device is ensured, the thickness of the first top barrier layer 18 can be adjusted according to actual situations.

In step S4, referring to FIGS. 1 and 5, the first filling layer 19 is formed on the first top barrier layer 18. The first filling layer 19 completely fills the first groove 15, and the top of the first filling layer 19 is flush with the top of each interlayer dielectric layer 142 by a chemical mechanical polishing process.

As an example, the method of forming the first filling layer 19 comprises a sputtering method, a physical vapor deposition method, a chemical vapor deposition method, a metal compound vapor deposition method, a molecular beam epitaxy method, an atomic vapor deposition method, an atomic layer deposition method, or other suitable methods.

Specifically, the first filling layer 19 is formed by a flowable chemical vapor deposition (FCVD) process. The first filling layer 19 fully fills the first groove 15 and extends to cover a top surface of the first top barrier layer 18. Next, the formed first filling layer 19 is planarized by a chemical mechanical polishing process, to expose the dummy gate layer 13 in the NMOS region. The top of the first filling layer 19 is flush with a top of the exposed dummy gate layer 13 in the NMOS region. As an example, the first filling layer 19 is made of amorphous silicon.

In step S5, referring to FIGS. 1, 6 and 7, also in patterning process, the first hard mask layer 20 and the second photoresist layer (not shown as an intermediate layer) are sequentially formed on the first filling layer 19 and the exposed dummy gate layer 13. The dummy gate layer 13, the second photoresist layer and the first hard mask layer 20 corresponding to the NMOS region are then removed by photolithography and etching to form the second groove 21. Finally, the remaining portion of the second photoresist layer is removed.

Specifically, as shown in FIG. 6, the first hard mask layer 20 is first formed to cover both the PMOS region and the NMOS region, serving as a protective layer for the PMOS region when subsequently etching the dummy gate layer 13 in the NMOS region, then the second photoresist layer (not shown) is formed on the first hard mask layer 20, then a second notch is formed using a photolithography process, so as to expose a to-be-etched region of the dummy gate layer 13 beneath the second notch. A width of the second notch determines a width of the subsequently formed NMOS region, as shown in FIG. 6. The exposed to-be-etched region of the dummy gate layer 13 beneath the second notch is removed by a dry etching process to form the second groove 21, and then the remaining portion of the second photoresist layer is removed.

Specifically, the second photoresist layer may be removed using an ashing method.

Specifically, as shown in FIG. 7, first, removing, by a dry etching process, a portion of the first hard mask layer 20 from above the NMOS region, wherein this being removed portion is slightly larger than the area of the NMOS region into the PMOS region, and meanwhile, the PMOS region will not be exposed after removing said portion of the first hard mask layer 20; then, removing the exposed dummy gate layer 13 by a wet etching process, applying a hydrochloric acid solution as an etching solution of the wet etching process. Since the first bottom barrier layer 16, the first work function metal layer 17 and the first top barrier layer 18 in the PMOS region help with reducing the junction damage between the PMOS region and the NMOS region, chamfer formation at the junction is eliminated, thereby preventing wet etching solutions from penetrating the PMOS metal gate. Because the first filling layer 19 within the PMOS region will be removed in a subsequent process, the reliability of the subsequently formed metal gate will remain unaffected even if a small amount of hydrochloric acid solution permeates into the PMOS region.

In step S6, referring to FIGS. 1, 8 and 9, the second bottom barrier layer 22, the second work function metal layer 23 and the second top barrier layer 24 on the bottom and the side walls of the second groove 21 are formed on the substrate 10 in the NMOS region, and the second filling layer 25 is formed on the second top barrier layer 24. The second filling layer 25 completely fills the second groove 21, and the top of the second filling layer 25 is flush with the top of the first filling layer 19 by a chemical mechanical polishing process.

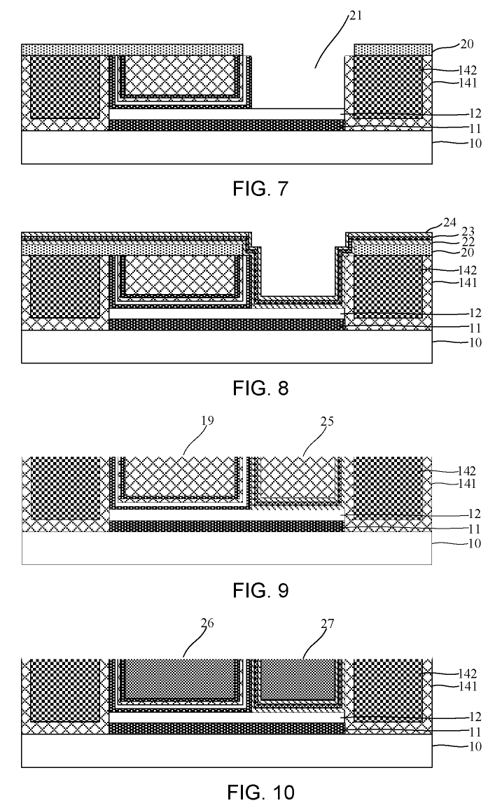

FIG. 8 shows a schematic cross-sectional view of an intermediate structure obtained after forming the second bottom barrier layer 22, the second work function metal layer 23 and the second top barrier layer 24. Specifically, the second bottom barrier layer 22 prevents metal gate diffusion in the NMOS region, blocking the metal gate from migrating into the first isolation layer 12, preserving the dielectric performance of the first isolation layer 12, and thereby enhancing the overall performance of the HKMG device.

Specifically, the method of forming the second bottom barrier layer 22, the second work function metal layer 23 and the second top barrier layer 24 comprises a sputtering method, a metal compound vapor deposition method, a molecular beam epitaxy method, an atomic vapor deposition method, an atomic layer deposition method, or other suitable methods.

Specifically, under the condition that the performance of the HKMG device is ensured, the thicknesses of the second bottom barrier layer 22, the second work function metal layer 23 and the second top barrier layer 24 can be adjusted according to actual situations.

As an example, a material of the second work function metal layer 23 comprises TiAl, TiAlC, or other suitable conductive materials. As an example, in the present disclosure, the second work function metal layer 23 is an N work function metal layer, TiAl is used to form the N work function metal layer, the effective work function of the HKMG device is adjusted using the second work function metal layer 23, so that the Fermi level of the NMOS region is close to the bottom of conduction band of the substrate 10.

As an example, a total thickness of the first bottom barrier layer 16, the first work function metal layer 17 and the first top barrier layer 18 is greater than a total thickness of the second bottom barrier layer 22, the second work function metal layer 23 and the second top barrier layer 24, such that a thickness of the second metal gate 27 formed by filling the metal material into the second groove 21 in the NMOS region is greater than a thickness of the first metal gate 26 formed by filling the metal material into the first groove 15 in the PMOS region.

As an example, the method of forming the second filling layer 25 comprises a sputtering method, a physical vapor deposition method, a chemical vapor deposition method, a metal compound vapor deposition method, a molecular beam epitaxy method, an atomic vapor deposition method, an atomic layer deposition method, or other suitable methods.

Specifically, as shown in FIG. 9, the second filling layer 25 is formed by an FCVD process. The second filling layer 25 fully fills the second groove 21 and extends to cover a top surface of the second top barrier layer 24. Next, the formed second filling layer 25 is planarized by a chemical mechanical polishing process, to expose the first filling layer 19 within the PMOS region. The top of the second filling layer 25 is flush with the top of the first filling layer 19. As an example, the second filling layer 25 is made of amorphous silicon.

In step S7, referring to FIGS. 1 and 10, the first filling layer 19 and the second filling layer 25 are removed by etching, followed by the deposition of metal material into the first groove 15 and second groove 21 to respectively form the first metal gate 26 and second metal gate 27. A chemical mechanical polishing process is then performed to ensure that the first and second metal gates 26 and 27 have a flush surface.

FIG. 10 shows a schematic cross-sectional view of an intermediate structure obtained after forming the first metal gate 26 and the second metal gate 27. Materials of the first metal gate 26 and the second metal gate 27 comprise Al, W, Ti, or any other conductive material suitable for work function. To simplify the process flow, the materials of the first metal gate 26 and the second metal gate 27 are kept the same, so that the first metal gate 26 and the second metal gate 27 can be manufactured through a single deposition and etching process.

Optionally, the method of forming the first metal gate 26 and the second metal gate 27 comprises a sputtering method, a metal compound vapor deposition method, a molecular beam epitaxy method, an atomic vapor deposition method, an atomic layer deposition method, or other suitable methods. Specifically, in the present disclosure, before the first metal gate 26 and the second metal gate 27 are deposited, the first filling layer 19 and the second filling layer 25 are first removed using an etching process, and the etched first groove 15 and second groove 21 are cleaned to ensure that amorphous silicon in the first groove 15 and the second groove 21 is completely removed, and then the metal material is deposited in the cleaned first groove 15 and second groove 21, so as to form the first metal gate 26 and the second metal gate 27. A chemical mechanical polishing process is then performed to ensure that the first and second metal gates 26 and 27 have a flush surface. Heights of the first metal gate 26 and the second metal gate 27 are equal to those of the first filling layer 19 and the second filling layer 25. The PMOS metal gate and the NMOS metal formed within the substrate 10 are isolated by the first bottom barrier layer 16, the first work function metal layer 17, the first top barrier layer 18, the second bottom barrier layer 22, the second work function metal layer 23, and the second top barrier layer 24.

The present disclosure further provides an HKMG device, as shown in FIG. 10. The HKMG device is manufactured using any of the aforementioned method embodiments.

As described above, the disclosed HKMG device and manufacturing method offer several advantages. By separately forming the first groove in the PMOS region and the second groove in the NMOS region, depositing the first filling layer in the PMOS region and the second filling layer in the NMOS region, then removing the first filling layer and the second filling layer through a combination of dry and wet etching and filling the grooves with metal material to respectively form the first and second metal gates, this method allows for precise control over etching depth and range, preventing interface damage to the PMOS region when removing polysilicon from the NMOS region in conventional processes; it effectively eliminates chamfer formation at the junction, prevents wet etching solutions from penetrating the PMOS metal gate, and fundamentally resolves corrosion defects caused by chemical reactions between wet etching solutions and metals like aluminum in traditional processes; furthermore, the PMOS and NMOS work function metal layers are formed stepwise, with chemical mechanical polishing ensuring a uniform surface, significantly enhancing the performance and reliability of the HKMG device. Therefore, the present disclosure effectively overcomes various shortcomings in the existing technology and has high industrial utilization value.

The above-mentioned embodiments are for exemplarily describing the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the scope of the present disclosure.

1. A method for manufacturing an HKMG device, comprising:
providing a substrate, forming a high-k dielectric layer, a first isolation layer, and a dummy gate layer on the substrate, and configuring the dummy gate layer with a side wall and an interlayer dielectric layer on each side;
performing photolithography and etching to open a first groove in the dummy gate layer, wherein the first groove in the dummy gate layer defines an NMOS region and a PMOS region;
forming a first bottom barrier layer, a first work function metal layer and a first top barrier layer on a bottom and side walls of the first groove on the substrate in the PMOS region;
forming a first filling layer on the first top barrier layer, wherein the first filling layer fills the first groove, and performing a chemical mechanical polishing process to get a top of the first filling layer flush with a top of the interlayer dielectric layer at each side;
performing photolithography and etching on a first hard mask layer on the first filling layer, removing the first hard mask layer and the dummy gate layer in the NMOS region to form a second groove;
forming a second bottom barrier layer, a second work function metal layer and a second top barrier layer on a bottom and side walls of the second groove on the substrate in the NMOS region, and forming a second filling layer on the second top barrier layer, wherein the second filling layer fills the second groove, and performing a chemical mechanical polishing process to get a top of the second filling layer flush with the top of the first filling layer; and
removing the first filling layer and the second filling layer by etching, depositing a metal material in the first groove and the second groove to respectively form a first metal gate and a second metal gate, and performing a chemical mechanical polishing process to make a top surface of the first metal gate flush with a top surface of the second metal gate flush with each other.

2. The method for manufacturing the HKMG device according to claim 1, wherein the first work function metal layer is a P work function metal layer, and the second work function metal layer is an N work function metal layer.

3. The method for manufacturing the HKMG device according to claim 2, wherein a material of the P work function metal layer comprises TiN, and a material of the N work function metal layer comprises TiAl.

4. The method for manufacturing the HKMG device according to claim 1, wherein the first bottom barrier layer comprises a first barrier layer and a second barrier layer which are stacked, wherein a material of the first barrier layer comprises TaN and TiN, and a material of the second barrier layer comprises TiN.

5. The method for manufacturing the HKMG device according to claim 1, wherein the first filling layer and the second filling layer are made of the same material and are both amorphous silicon; wherein the dummy gate layer is made of the same material as the first filling layer and the second filling layer.

6. The method for manufacturing the HKMG device according to claim 1, wherein the first metal gate and the second metal gate are made of the same material, comprising Al, W, and Ti.

7. The method for manufacturing the HKMG device according to claim 1, wherein removing the first hard mask layer and the dummy gate layer in the NMOS region comprises: removing the first hard mask layer by a dry etching process, and removing the dummy gate layer by a wet etching process, wherein an etching solution of the wet etching process is a hydrochloric acid solution.

8. The method for manufacturing the HKMG device according to claim 7, further comprising: removing a portion of the first hard mask layer from above the NMOS region, wherein said removed portion is larger than an area of the NMOS region into the PMOS region, and wherein the PMOS region is kept unexposed after removing said portion of the first hard mask layer from the first hard mask layer.

9. The method for manufacturing the HKMG device according to claim 1, wherein a total thickness of the first bottom barrier layer, the first work function metal layer and the first top barrier layer is greater than a total thickness of the second bottom barrier layer, the second work function metal layer and the second top barrier layer.

10. An HKMG device, manufactured using the method according to claim 1.
